(19) United States
(12) Patent Application Publication
(10) Pub. No.: US 2014/0293682 A1
(43) Pub. Date: Oct. 2, 2014

(54) MEMORY BITCELL CLUSTERS EMPLOYING LOCALIZED GENERATION OF COMPLEMENTARY BITLINES TO REDUCE MEMORY AREA, AND RELATED SYSTEMS AND METHODS

(71) Applicant: QUALCOMM Incorporated, San Diego, CA (US)

(72) Inventors: Chintan H. Shah, Apex, NC (US); Yeshwant Nagaraj Kolla, Wake Forest, NC (US)

(21) Appl. No.: 13/910,215

(22) Filed: Jun. 5, 2013

Related U.S. Application Data
(60) Provisional application No. 61/806,121, filed on Mar. 28, 2013.

(51) Int. Cl. G11C 11/412; G11C 11/413

(52) U.S. Cl. CPC G11C 11/412; G11C 11/413
USPC 365/156

(57) ABSTRACT

Embodiments disclosed include memory bitcell clusters employing localized generation of complementary bitlines to reduce memory area. The memory bitcell clusters disclosed may be static random access memory (SRAM) used as central processing unit (CPU) register files. The memory bitcell clusters disclosed include a plurality of memory bitcells that share a common bitline. To reduce area required to provide complementary bitlines for the memory bitcells, the memory bitcell clusters include a localized inverter circuit. The localized inverter circuit is configured to invert a common bitline localized to the memory bitcells to provide a complementary bitline for the memory bitcells in the memory bitcell cluster. Because the inverter circuit is localized to the memory bitcells, a track in a semiconductor die for the complementary bitline does not extend beyond the memory bitcell cluster, minimizing the complexity of the memory bitcell cluster by reducing a number of bitline tracks used by half.

### PRIORITY CLAIM

The present application claims priority to U.S. Provisional Patent Application Ser. No. 61/806,121 filed on Mar. 28, 2013 and entitled “MEMORY BITCELL CLUSTERS EMPLOYING LOCALIZED GENERATION OF COMPLEMENTARY BITLINES TO REDUCE AREA, AND RELATED SYSTEMS AND METHODS,” which is incorporated herein by reference in its entirety.

### BACKGROUND

I. Field of the Disclosure

The technology of the disclosure relates to multi-port memory bitcell clusters, including central processing unit (CPU) register files and static random access memory (SRAM) cells.

II. Background

A memory cell is a basic building block of computer data storage, known as “memory.” A computer system may either read data from or write data to memory. There are different types of memory. For example, one type of memory is static random access memory (SRAM). SRAM may be used as register files in a central processing unit (CPU) system, as a non-limiting example. SRAM is comprised of a plurality of SRAM bitcells organized in rows and columns. SRAM bitcell access is controlled by a corresponding wordline for read and write operations. The wordline is used to select a desired row of SRAM bitcells for a read or write operation. A complementary wordline may also be employed to improve noise margins when selecting the desired row in SRAM for a read or write operation. A bitline carries data for SRAM bitcell read and write operations. For a SRAM read or write operation, a wordline is asserted to select a desired row of SRAM bitcells. For a read operation, data read from the selected SRAM bitcells is placed on a corresponding bitline and a complementary bitline. For a write operation, data to be written to the SRAM bitcell is placed on the corresponding bitline and the complementary bitline for the SRAM bitcell. Thus, for a complementary bitline architecture employed for SRAM, every SRAM bitcell includes two bitlines. Providing a bitline and a complementary bitline for every bitcell in SRAM requires additional area in a semiconductor die to provide for the two bitlines.

For CPU architectures that employ execution pipelines, it may be desirable to provide for different pipeline stages that are each capable of reading data from and writing data to SRAM. In this regard, the SRAM bitcells may include multiple read and write ports to facilitate different pipeline stages each having the independent ability to read data from and write data to the SRAM bitcells. SRAM bitcells employing multiple read and write ports are also known as “multi-port” SRAM bitcells. The number of read and write ports provided in a SRAM bitcell is dependent upon CPU architecture.

Multi-port SRAM can provide performance advantages for a CPU architecture. However, providing multi-port SRAM also increases the area required in a semiconductor die for the SRAM bitcells. For every read and write port provided in a SRAM bitcell, the required number of additional wordlines and bitlines increases linearly. Thus, the additional space required for the wordlines and the bitlines in a semiconductor die for a multi-port SRAM also increases in kind. Providing additional wordlines and bitlines in SRAM also creates significant complexity when combined with the supporting circuitry for memory. The complexity can become costly in terms of area usage on the semiconductor die. Further, any additional area required for memory bitcells increases board size, which may need to be conserved or used for other components.

### SUMMARY OF THE DISCLOSURE

Embodiments disclosed herein include memory bitcell clusters employing localized generation of complementary bitlines to reduce memory area. Related systems and methods are also disclosed. A memory bitcell cluster is a grouping of two or more adjacent memory bitcells in a semiconductor die or integrated circuit (IC) that share a common inverter circuit to provide for common complementary bitlines. The memory bitcell clusters disclosed herein may be static random access memory (SRAM) used as central processing unit (CPU) register files, as one non-limiting example. The memory bitcell clusters disclosed herein include a plurality of memory bitcells that share a common bitline. In one embodiment, to reduce area in a semiconductor die or IC required to provide complementary bitlines for the memory bitcells, the memory bitcell clusters include a localized inverter circuit. The localized inverter circuit is configured to invert the common bitline localized to the memory bitcell clusters to provide a shared complementary bitline for the memory bitcell clusters. By localized, it is meant that the complementary bitlines do not extend beyond a cluster of memory bitcells contained in a semiconductor die containing the memory. Because the inverter circuit is localized to the memory bitcells, a track provided in the semiconductor die for the complementary bitline does not have to extend beyond the memory bitcell cluster. As a result, the number of required bitline tracks that extend beyond the memory bitcell cluster can be reduced. The memory bitcell cluster can also reduce the number of inverters required to produce complementary bitlines, thus reducing power consumption.

In this regard in one embodiment, a memory bitcell cluster is provided. The memory bitcell cluster comprises a first bitcell. The first bitcell comprises a first bit storage unit and a first wordline port configured to receive a first data access request from a first wordline to provide data access to the first bit storage unit. The first bitcell further comprises a first bitline port configured to carry data corresponding to the first bit storage unit on a bitline. The first bitcell also comprises a first complementary bitline port configured to carry complementary data corresponding to the first bit storage unit on a complementary bitline. The memory bitcell cluster also comprises a second bitcell adjacent to the first bitcell. The second bitcell comprises a second bit storage unit and a second wordline port configured to receive a second data access request from a second wordline to provide data access to the second bit storage unit. The second bitcell further comprises a second bitline port configured to carry data corresponding to the second bit storage unit on the bitline and a second complementary bitline port configured to carry complementary data corresponding to the second bit storage unit on the complementary bitline. The memory bitcell cluster also comprises an inverter circuit configured to receive data on the bitline in an inverter input port, and invert the data to provide corresponding complementary data on an inverter output port to provide the complementary bitline. The inverter circuit may be a localized inverter circuit localized to the memory bitcell cluster if it is desired to provide for the complementary bitlines to not extend beyond the memory bitcell cluster.

In this regard, in another embodiment, a memory bitcell cluster for inverting a received first data access request and a received second data access request in a second memory bitcell cluster is provided. The memory bitcell cluster comprises a means for receiving a first data access request in a first bitcell means comprising a first bit storage means. The first bitcell means further comprises a first wordline port means configured to receive the first data access request from a first wordline means to provide data access to the first bit storage means. The first bitcell means further comprises a first bitline port means configured to carry data corresponding to the first bit storage means on a bitline means and a first complementary bitline port means configured to carry complementary data corresponding to the first bit storage means on a complementary bitline means. The memory bitcell cluster further comprises a means for receiving a second data access request in a second bitcell means adjacent to the first bitcell means. The second bitcell means comprises a second bit storage means, a second wordline port means configured to receive the second data access request from a second wordline means to provide data access to the second bit storage means, and a second bitline port means configured to carry data corresponding to the second bit storage means on the bitline means. The second bitcell means further comprises a second complementary bitline port means configured to carry complementary data corresponding to the second bit storage means on the complementary bitline means. The memory bitcell cluster further comprises a means for inverting. The means for inverting comprises an inverter circuit means configured to receive data on the bitline means in an inverter input port means. The inverter circuit means is also configured to invert the data to provide corresponding complementary data on an inverter output port means to provide the complementary bitline means.

In another embodiment, a method of localizing complementary bitlines in a memory bitcell cluster is provided. The method comprises receiving a first data access request in a first bitcell comprising a first bit storage unit. Receiving the first data access request in the first bitcell comprises receiving, at a first wordline port, the first data access request from a first wordline to provide data access to the first bit storage unit. Receiving the first data access request in the first bitcell further comprises carrying data on a first bitline port corresponding to the first bit storage unit on a bitline. Receiving the first data access request in the first bitcell further comprises carrying complementary data on a first complementary bitline port corresponding to the first bit storage unit on a first complementary bitline. The method further comprises receiving a second data access request in a second bitcell adjacent to the first bitcell. Receiving the second data access request in the second bitcell comprises receiving, at a second wordline port, the second data access request from a second wordline to provide data access to a second bit storage unit. Receiving the second data access request in the second bitcell further comprises carrying data on a second bitline port corresponding to the second bit storage unit on the bitline. Receiving the second data access request in the second bitcell further comprises carrying complementary data on a second complementary bitline port corresponding to the second bit storage unit on a second complementary bitline. The method further comprises receiving data at an inverter input port of an inverter circuit and inverting the data received at the inverter input port of the inverter circuit to provide corresponding complementary data on an inverter output port to provide the complementary bitline.

### BRIEF DESCRIPTION OF THE FIGURES

FIG. 1 is a block diagram of an exemplary generalized representation of a memory bitcell cluster comprising two adjacent memory bitcells and inverters to generate localized complementary bitlines in between the two adjacent memory bitcells;

FIG. 2 is a block diagram of an exemplary generalized representation of a multi-port memory bitcell cluster comprising two adjacent memory bitcells and inverters to generate localized complementary bitlines in between the two adjacent memory bitcells;

FIG. 3A is an exemplary schematic a memory bitcell cluster comprising two adjacent memory bitcells and an inverter circuit, wherein the inverter circuit comprises inverters to generate localized complementary bitlines in between the two adjacent memory bitcells;

FIG. 3B is an exemplary side view schematic of a memory bitcell cluster comprising two adjacent memory bitcells and an inverter circuit, wherein the inverter circuit comprises inverters to generate localized complementary bitlines in between the two adjacent memory bitcells, wherein the side view schematic illustrates localized track usage in metal layers;

FIG. 4 is an exemplary schematic and layout of a memory bitcell cluster comprising the two adjacent memory bitcells and the inverter circuit of FIG. 3A, showing metal track usage for the two adjacent memory bitcells and the inverter circuit in a multi-port memory bitcell cluster in metal layers;

FIG. 5 is an exemplary schematic of a memory bitcell cluster comprising the two adjacent memory bitcells and the inverter circuit of FIG. 3A, showing a horizontal bitline track in a multi-port memory bitcell and a metal layer; and

FIG. 6 is a block diagram of an exemplary processor-based system that can include the memory bitcell clusters according to the embodiments disclosed herein, including but not limited to the memory bitcell clusters of FIGS. 1-5.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed herein include memory bitcell clusters employing localized generation of complementary bitlines to reduce memory area. Related systems and methods are also disclosed. A memory bitcell cluster is a grouping of two or more adjacent memory bitcells in a semiconductor die or integrated circuit (IC) that share a common inverter circuit to provide for common complementary bitlines. The memory bitcell clusters disclosed herein may be static random access memory (SRAM) used as central processing unit (CPU) register files, as one non-limiting example. The memory bitcell clusters disclosed herein include a plurality of memory bitcells that share a common bitline. In one embodiment, to reduce area in a semiconductor die or IC required to provide complementary bitlines for the memory bitcells, the memory bitcell clusters include a localized inverter circuit. The localized inverter circuit is configured to invert the common bitline localized to the memory bitcell clusters to provide a shared complementary bitline for the memory bitcell clusters. By localized, it is meant that the complementary bitlines do not extend beyond a cluster of memory bitcells contained in a semiconductor die containing the memory. Because the inverter circuit is localized to the memory bitcells, a track provided in the semiconductor die for the complementary bitline does not have to extend beyond the memory bitcell cluster. As a result, the number of required bitline tracks that extend beyond the memory bitcell cluster can be reduced. The memory bitcell cluster can also reduce the number of inverters required to produce complementary bitlines, thus reducing power consumption.

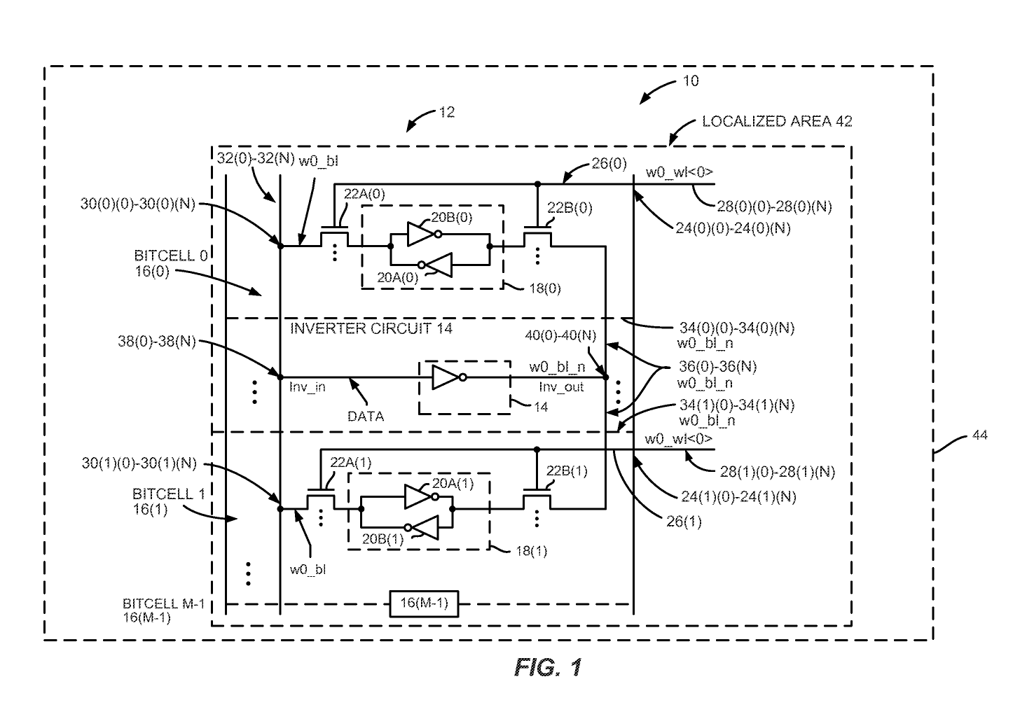

In this regard in one embodiment, an exemplary memory bitcell cluster 10 of a memory 12 is provided in FIG. 1. In this embodiment, the memory bitcell cluster 10 is a SRAM bitcell cluster in the memory 12 provided as SRAM memory. As will be described in more detail below, the memory bitcell cluster 10 in FIG. 1 includes a localized inverter circuit 14 configured to invert a common bitline localized to the memory bitcell cluster 10 to provide a shared complementary bitline for the memory bitcell cluster 10. In this manner, the area needed in a semiconductor die or IC (not shown) to provide complementary bitlines for the memory bitcell cluster 10 can be reduced. Also, because the inverter circuit 14 can be localized to the memory bitcell cluster 10, a track in a semiconductor die for the complementary bitline does not have to extend beyond the memory bitcell cluster 10. Before discussing the exemplary details regarding the localized inverter circuit 14, a brief discussion of the components of the memory bitcell cluster 10 is first provided below.

In this embodiment, the memory bitcell cluster 10 in FIG. 1 is SRAM. The memory bitcell cluster 10 comprises a first memory bitcell 16(0) (i.e. Bitcell 1) and a second memory bitcell 16(1) (i.e. Bitcell 2). The first memory bitcell 16(0) is located adjacent to the second memory bitcell 16(1) in the memory bitcell cluster 10. Note that the memory bitcell cluster 10 in FIG. 1 is not limited to two memory bitcells 16(0), 16(1). The memory bitcell cluster 10 may comprise up to ‘M’ memory bitcells 16(0)-16(M−1), where ‘M’ is the number of memory bitcells.

With continuing reference to FIG. 1, the first memory bitcell 16(0) comprises a first bit storage unit 18(0). In this embodiment, the first bit storage unit 18(0) is a six-transistor (6T) SRAM unit. The first bit storage unit 18(0) is formed with two cross-coupled inverters 20(0). The two cross-coupled inverters 20A(0), 20B(0) may be comprised of four transistors in a standard 6T SRAM unit configuration (not shown). The two cross-coupled inverters 20A(0), 20B(0) have two stable states denoted or associated with a logical zero (0) or a logical one (1). Two additional access transistors 22A(0), 22B(0) serve to control access to the first bit storage unit 18(0). The first memory bitcell 16(0) further comprises a first write wordline port 24(0)(0)-24(0)(N) (w0_wl<0>) coupled to the two access transistors 22A(0), 22B(0). The first write wordline port 24(0)(0)-24(0)(N) is configured to receive a first data access request 26(0) from a first write wordline 28(0)(0)-28(0)(N). By receiving the first data access request 26(0), the first write wordline 28(0)(0)-28(0)(N) asserts the access transistors 22A(0), 22A(0) coupled to the first memory bitcell 16(0). Asserting the access transistors 22A(0), 22B(0) coupled to the first memory bitcell 16(0) provides data access to the first bit storage unit 18(0). The first memory bitcell 16(0) further comprises a first write bitline port 30(0)(0)-30(0)(N) configured to carry data corresponding to the first bit storage unit 18(0) on a write bitline 32(0)-32(N) (w0_bl). The first memory bitcell 16(0) further comprises a first complementary write bitline port 34(0)(0)-34(0)(N) (w0_bl_n) configured to receive data corresponding to the first bit storage unit 18(0). The corresponding data received at the first complementary write bitline port 34(0)(0)-34(0)(N) is complementary data corresponding to the first bit storage unit 18(0) carried by a complementary write bitline 36(0)-36(N) (w0_bl_n).

With continuing reference to FIG. 1, the memory bitcell cluster 10 further comprises a second memory bitcell 16(1) adjacent to the first memory bitcell 16(0). The second memory bitcell 16(1) comprises a second bit storage unit 18(1). The second bit storage unit 18(1) includes similar components to the first bit storage unit 18(0). The second bit storage unit 18(1) is formed with two cross-coupled inverters 20A(1), 20B(1). The two cross-coupled inverters 20A(1), 20B(1) are comprised of four transistors (not shown) in a standard 6T SRAM unit configuration. The two cross-coupled inverters 20A(1), 20B(1) have two stable states denoted or associated with a logical zero (0) or a logical one (1). The second memory bitcell 16(1) includes a second write wordline port 24(1)(0)-24(1)(N) (w0_wl<1>) configured to receive a second data access request 26(1) from a second write wordline 28(1)(0)-28(1)(N). By receiving the second data access request 26(1), the second write wordline 28(1)(0)-28(1)(N) asserts two access transistors 22A(1), 22B(1) on the second memory bitcell 16(1). Asserting the access transistors 22A(1), 22B(1) on the second memory bitcell 16(1) provides data access to the second bit storage unit 18(1). The second memory bitcell 16(1) further comprises a second write bitline port 30(1)(0)-30(1)(N) (w0_bl) configured to carry data corresponding to the second bit storage unit 18(1) on the write bitline 32. The second memory bitcell 16(1) further comprises a second complementary write bitline port 34(1)(0)-34(1)(N) configured to receive data corresponding to the second bit storage unit 18(1). The corresponding data received at the second complementary write bitline port 34(1)(0)-34(1)(N) is complementary data corresponding to the second bit storage unit 18(1) carried by the complementary write bitline 36(0)-36(N).

The memory bitcell cluster 10 further comprises an inverter circuit 14. The inverter circuit 14 is configured to receive data on the write bitline 32(0)-32(N) in an inverter input port 38(0)-38(N) (Inv_in). The inverter circuit 14 is further configured to generate localized inverted data to provide corresponding complementary data on an inverter output port 40(0)-40(N) (Inv_out) to provide the complementary write bitline 36(0)-36(N). The inverter circuit 14 generates the localized inverted data in a localized memory bitcell cluster region 42. The localized memory bitcell cluster region 42 is the area comprising the memory bitcell cluster 10 and immediately supporting devices and circuitry for the memory bitcell cluster 10. Localized is a term used to refer to the area comprising the memory bitcell cluster 10. In this manner, only the write bitline 32(0)-32(N) is routed from outside the localized memory bitcell cluster region 42 in this embodiment. The complementary write bitline 36(0)-36(N) is locally generated within the localized memory bitcell cluster region 42 and not routed in a semiconductor die 44 outside the localized memory bitcell cluster region 42.

In this regard, the number of required bitline tracks (not shown) that extend beyond the memory bitcell cluster 10 can be reduced. The memory bitcell cluster 10 can also reduce the number of inverters (not shown) required to produce complementary bitlines, thus reducing power consumption. In an alternative embodiment, the memory bitcell cluster 10 is not limited to two memory bitcells 16(0), 16(1). Again, the memory bitcell cluster 10 may include up to ‘M’ memory bitcells 16(0)-16(M−1); where ‘M’ is the number of memory bitcells included. The memory bitcell cluster 10 may also be comprised of memory bitcells 16(0), 16(1) with multiple ports to allow multiple devices or CPU pipelines to perform read and/or write operations in the memory 12.

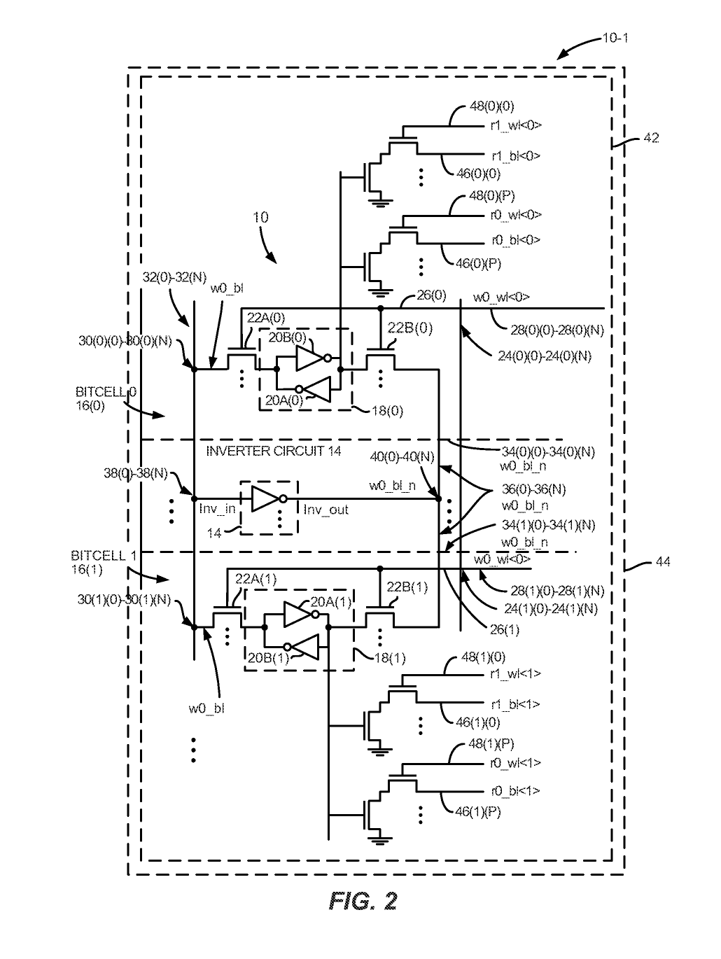

In this regard, FIG. 2 is an exemplary schematic diagram illustrating a multi-port memory bitcell cluster 10-1. The multi-port memory bitcell cluster 10-1 in this embodiment is comprised of a plurality of write bitlines 32(0)-32(N) and a plurality of write wordlines 28(0)(0)-28(0)(N), 28(1)(0)-28(1)(N) similar to that provided in the memory bitcell cluster 10 in FIG. 1. In this exemplary embodiment, the multi-port memory bitcell cluster 10-1 operates to allow multiple devices or CPU pipelines to perform read and/or write operations from the same memory bitcell 16. Similar to the memory bitcell cluster 10 in FIG. 1, the multi-port memory bitcell cluster 10-1 localizes the generation of the complementary write bitlines 36(0)-36(N). Common elements between the multi-port memory bitcell cluster 10-1 in FIG. 2 and the memory bitcell cluster 10 in FIG. 1 share common element numbers, and thus will not be re-described here. FIG. 2 additionally illustrates the multi-port memory bitcell cluster 10-1 comprising a plurality of first read bitlines 46(0)(0)-46(0)(P) (r0_bl−rP_bl), where P is the number of first read bitlines 46(0)(0)-46(0)(P) and a plurality of second read bitlines 46(1)(0)-46(1)(P) for reading the contents of the first and second memory bitcells 16(0), 16(1). FIG. 2 also comprises a plurality of first read wordlines 48(0)(0)-48(0)(P) and a plurality of second read wordlines 48(1)(0)-48(1)(P). The first read wordlines 48(0)(0)-48(0)(P) control read access to the first memory bitcell 16(0) in a similar fashion to the way the first write wordline 28(0)(0)-28(0)(N) controls write access to the first memory bitcell 16(0). The respective wordline 48(0)(0)-48(0)(P), 48(1)(0)-48(1)(P), is asserted thereby allowing the corresponding read bitline 46(0)(0)-46(0)(P), 46(1)(0)-46(1)(P) to be read. A read operation is initiated by asserting the appropriate first read wordline 48(0)(0)-48(0)(P). By asserting the appropriate first read wordline 48(0)(0)-48(0)(P) the contents of the first memory bitcell 16(0) are read on the corresponding first read bitline 46(0)(0)-46(0)(P). Similarly, by asserting the appropriate second read wordline 48(1)(0)-48(1)(P), the contents of the second memory bitcell 16(1) are read on the corresponding second read bitline 46(1)(0)-46(1)(P).

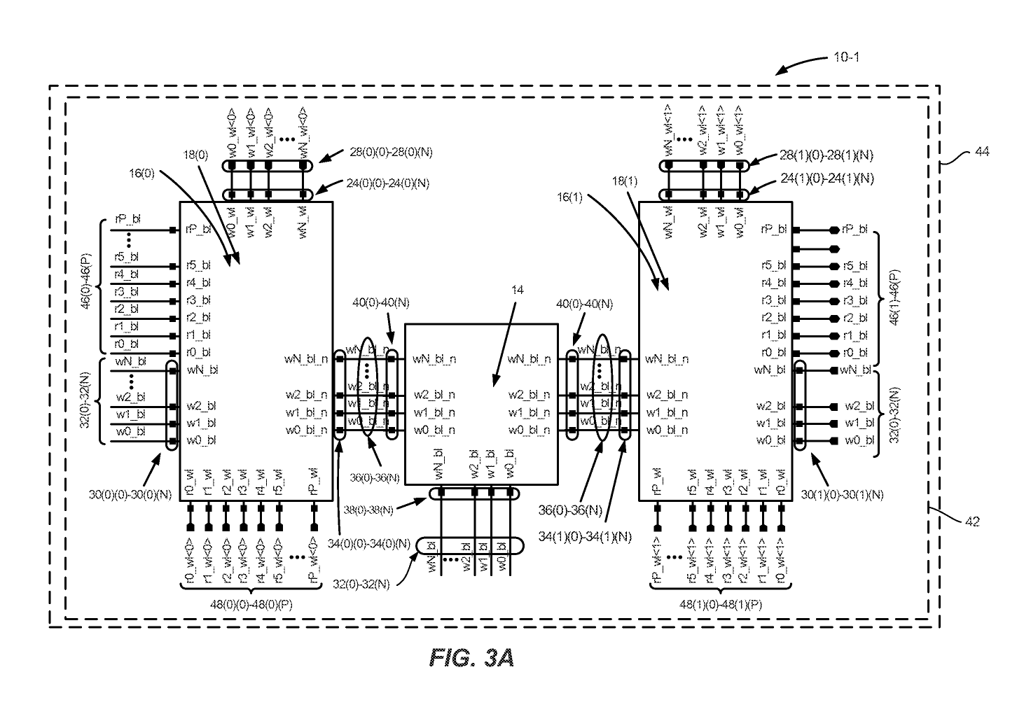

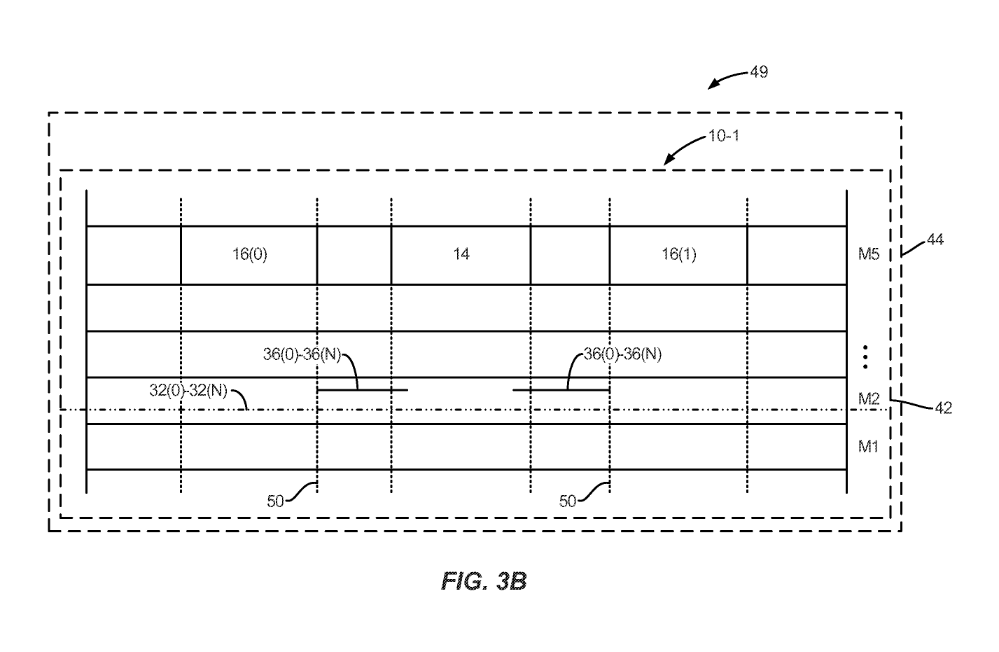

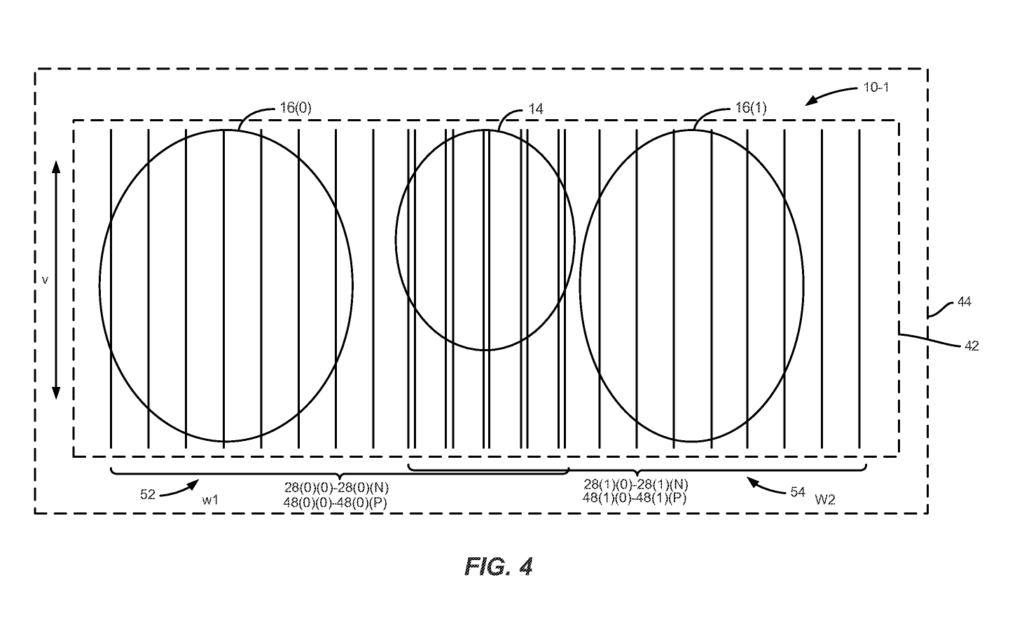

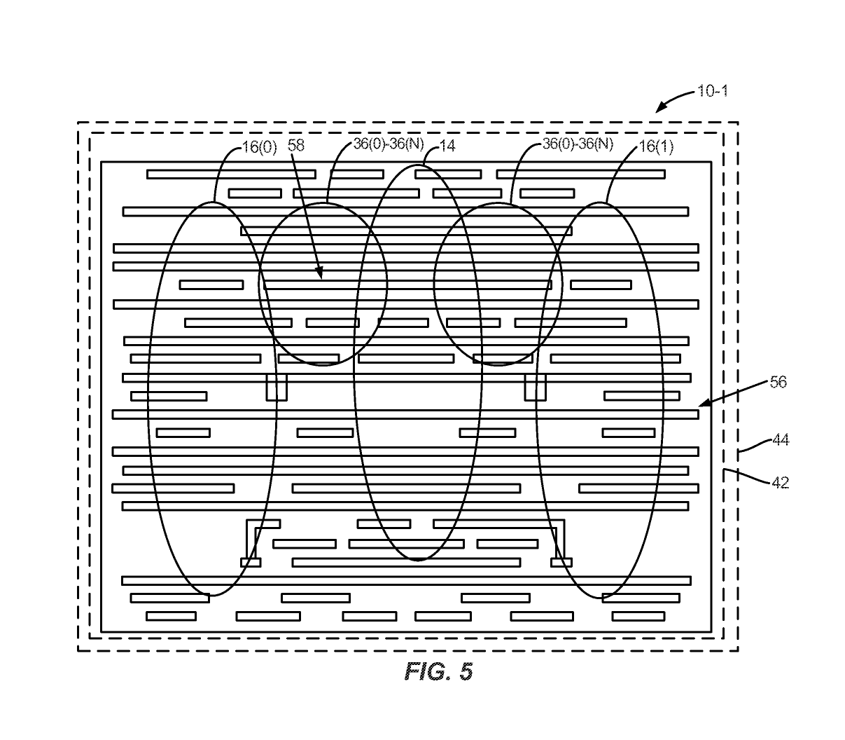

In this regard, FIG. 3A is an exemplary semiconductor track layout diagram of a memory bitcell cluster 10-1. The memory bitcell cluster 10-1 could be included in SRAM and/or a multi-port register file, as non-limiting examples. A multi-port register file is an array of processor registers in a CPU. Integrated circuit-based multi-port register files may, for example, be implemented as fast SRAMs with multiple ports. The exemplary schematic diagram of the memory bitcell cluster 10-1 illustrates the physical separation of the first memory bitcell 16(0) and the second memory bitcell 16(1) based on the size and width of the read wordlines 48(0)(0)-48(0)(P), 48(1)(0)-48(1)(P), and the write wordlines 28(0)(0)-28(0)(N), 28(1)(0)-28(1)(N), for each memory bitcell 16(0), 16(1). The physical separation occurs because the wordlines use physical tracks in metal layers (e.g. metal 1, metal 2, etc.) to route the circuitry, as will be discussed in FIG. 4 and FIG. 5. The memory bitcell cluster 10-1 comprises two similar multi-port memory bitcells 16(0), 16(1), and inverter circuits 14 localized between the multi-port memory bitcells 16(0), 16(1). The inverter circuits 14 can be localized between the multi-port memory bitcells 16(0), 16(1), because of the physical separation caused by the width of the read wordlines 48(0)(0)-48(0)(P), 48(1)(0)-48(1)(P) and write wordlines 28(0)(0)-28(0)(N), 28(1)(0)-28(1)(N), in each memory bitcell 16(0), 16(1). In this regard, the memory bitcell cluster 10-1 comprises a first multi-port memory bitcell 16(0), which comprises a first multi-port bit storage unit 18(0). The first multi-port memory bitcell 16(0) further comprises a plurality of first write wordline ports 24(0)(0)-24(0)(N) (w0_wl<0>−wN_wl<4>) similar to the first write wordline port 24(0)(0)-24(0)(N) of FIG. 1. The plurality of first write wordline ports 24(0)(0)-24(0)(N) is configured to receive a first data access request (not shown) from a plurality of first write wordlines 28(0)(0)-28(0)(N) to provide data access to the first multi-port bit storage unit 18(0). The first multi-port memory bitcell 16(0) further comprises a plurality of first write bitline ports 30(0)(0)-30(0)(N) (w0_bl−wN_bl) configured to carry data corresponding to the first multi-port bit storage unit 18(0) on write bitlines 32(0)-32(N) (w0_bl−wN_bl). The first multi-port memory bitcell 16(0) further comprises a plurality of first complementary write bitline ports 34(0)(0)-34(0)(N) configured to receive data corresponding to the first multi-port bit storage unit 18(0). The corresponding data received at the plurality of first complementary write bitline ports 34(0)(0)-34(0)(N) is complementary data corresponding to the first multi-port bit storage unit 18(0) carried by a plurality of complementary write bitlines 36(0)-36(N) (w0_bl_n−wN_bl_n).

With continuing reference to FIG. 3A, the memory bitcell cluster 10-1 further comprises a second multi-port memory bitcell 16(1) adjacent to the first multi-port memory bitcell 16(0). The second multi-port memory bitcell 16(1) comprises a second multi-port bit storage unit 18(1). The second multi-port memory bitcell 16(1) further comprises a plurality of second write wordline ports 24(1)(0)-24(1)(N) (w0_wl<1>−wN_wl<1>), similar to the second write wordline port 24(1)(0)-24(1)(N) in the memory bitcell cluster 10 in FIG. 1. The plurality of second write wordline ports 24(1)(0)-24(1)(N) is configured to receive a second data access request (not shown) from a plurality of second write wordlines 28(1)(0)-28(1)(N) to provide data access to the second multi-port bit storage unit 18(1). A plurality of second write bitline ports 30(1)(0)-30(1)(N) is configured to carry data corresponding to the second multi-port bit storage unit 18(1) on the plurality of write bitlines 32(0)-32(N). The second multi-port memory bitcell 16(1) further comprises a plurality of second complementary write bitline ports 34(1)(0)-34(1)(N) (w0_bl_n−wN_bl_n) configured to receive data corresponding to the second multi-port bit storage unit 18(1). The corresponding data received at the plurality of second complementary write bitline ports 34(1)(0)-34(1)N) is complementary data corresponding to the second multi-port bit storage unit 18(1) on the plurality of complementary write bitlines 36(0)-36(N).

The memory bitcell cluster 10-1 of FIG. 3A further comprises the inverter circuits 14 configured to receive data on the plurality of write bitlines 32(0)-32(N) in a plurality of inverter input ports 38(0)-38(N). The inverter input ports 38(0)-38(N) are also known as “inverter inputs”. The inverter circuits 14 is further configured to invert the data to provide corresponding complementary data on a plurality of inverter output ports 40(0)-40(N) to provide the plurality of complementary write bitlines 36(0)-36(N) to the plurality of first complementary write bitline ports 34(0)(0)-34(0)(N) and the plurality of second complementary write bitline ports 34(1)(0)-34(1)(N). In the alternative, the plurality of inverter input ports 38(0)-38(N) may be coupled to a bitline complement (not shown) with the inverter circuits 14 for inverting the received complementary write bitlines 36(0)-36(N), and outputting non-complemented write bitlines 32(0)-32(N). In the alternative scenario, the multi-port memory bitcells 16(0), 16(1) receive the complementary write bitlines 36(0)-36(N) on the plurality of first complementary write bitline ports 34(0)(0)-34(0)(N) and the plurality of second complementary write bitline ports 34(1)(0)-34(1)(N). Further, if the complementary write bitlines are received on the first and second complementary write bitline ports 34(0)(0)-34(0)(N), 34(1)(0)-34(1)(N), then the plurality of first and second complementary write bitline ports 34(0)(0)-34(0)(N), 34(1)(0)-34(1)(N) is configured to receive the inverse of the bitline complement data or the bitline data.

With continuing reference to FIG. 3A, in the exemplary schematic of the memory bitcell cluster 10-1, the first multi-port memory bitcell 16(0) is comprised of a plurality of first read bitlines 46(0)(0)-46(0)(P) and a plurality of first read wordlines 48(0)(0)-48(0)(P). The second multi-port memory bitcell 16(1) is comprised of a plurality of second read bitlines 46(1)(0)-46(1)(P) and a plurality of second read wordlines 48(1)(0)-48(1)(P). The plurality of first read bitlines 46(0)(0)-46(0)(P) and the plurality of first read wordlines 48(0)(0)-48(0)(P) are separate and distinct from the plurality of write bitlines 32(0)-32(N) and the plurality of first write wordlines 28(0)(0)-28(0)(N). While the write bitlines 32(0)-32(N) and the first write wordlines 28(0)(0)-28(0)(N) are used for writing to the multi-port memory bitcells 16(0), 16(1), the plurality of first read bitlines 46(0)(0)-46(0)(P) and the plurality of first read wordlines 48(0)(0)-48(0)(P) are used to read from the multi-port memory bitcells 16(0), 16(1). A read operation from the multi-port memory bitcells 16(0), 16(1) occurs as one of the plurality of first read wordlines 48(0)(0)-48(0)(P) is asserted. As one of the plurality of first read wordlines 48(0)(0)-48(0)(P) is asserted, the data value stored in the first memory bit storage unit 18(0) is placed on the corresponding first read bitline 46(0)(0)-46(0)(P). As the data value is placed on the corresponding first read bitline 46(0)(0)-46(0)(P), the data value is then read thereby completing the read operation from the first memory bitcell 16(0). The purpose of the plurality of read and write bitlines and the plurality of read and write wordlines is to allow for CPU architectures that employ execution pipelines to provide for different pipeline stages that are each capable of reading data from and writing data to the multi-port memory bitcells 16(0), 16(1). In this manner, the first read wordlines 48(0)(0)-48(0)(P) are used to allow read access on the corresponding first read bitlines 46(0)(0)-46(0)(P) for the first multi-port memory bitcell 16(0). For instance, if a first read wordline 48(0)(0)-48(0)(P) r0_wl<0> is asserted, then the data contained in the first multi-port bit storage unit 18(0) will be read on a first read bitline 46(0)(0)-46(0)(P) r0_bl<0>. As a similar example, if a second read wordline 48(1)(0)-48(1)(P) r0_wl<1> is asserted, then the data contained in the second multi-port bit storage unit 18(1) will be read on a second read bitline 46(1)(0)-46(1)(P) r0_bl<1>. The exemplary memory bitcell cluster 10-1 requires tracks in the metal layers of a semiconductor die 44 to couple the bitlines, complementary bitlines, and the wordlines of the multi-port memory bitcells 16(0), 16(1) and the inverter circuits 14 of FIG. 3A. Each track takes up physical width in the semiconductor die 44.

In this regard and with continuing reference to FIG. 3A, the two multi-port memory bitcells 16(0), 16(1) are fixed in physical width (not shown) on the semiconductor die 44 based on the combined number of first and second read wordlines 48(0)(0)-48(0)(P), 48(1)(0)-48(1)(P) and the first and second write wordlines 28(0)(0)-28(0)(N), 28(1)(0)-28(1)(N). The fixed physical width is referred to as being metal limited and will be discussed further below in regard to FIG. 3B. Metal layers in the semiconductor die 44 are used for the placement of devices and circuit routing. Circuit routing may include routing of both memory bitlines and wordlines. In this example, the multi-port memory bitcells 16(0), 16(1) include thirteen (13) ports. The thirteen (13) ports include both read and write ports. The metal tracks used for routing of the wordlines require space to allow for the routing of the tracks. The routing of the tracks creates a space gap on the semiconductor die 44 between the two multi-port memory bitcells 16(0), 16(1) because the two multi-port memory bitcells 16(0), 16(1) are located as close as possible to each other. In this example, as will be discussed further in FIG. 3B, a space gap between the multi-port memory bitcell 16(0) and the multi-port memory bitcell 16(1) is created, because the multi-port memory bitcells 16(0), 16(1) may not be physically located any closer to one another due to the thickness and number of wordline tracks. The physical location limitation is also known as being “metal limited”. The created gap due to this metal limitation, allows for additional devices to be positioned between the two multi-port memory bitcells 16(0), 16(1) without increasing the size of the semiconductor die 44 in this example. In this example, the inverter circuits 14 are positioned between the two multi-port memory bitcells 16(0), 16(1). Positioning the inverter circuits 14 between the two multi-port memory bitcells 16(0), 16(1) allows the plurality of complementary write bitlines 36(0)-36(N) to be generated locally based on a received plurality of write bitlines 32(0)-32(N). Local generation of a plurality of complementary write bitlines 36(0) —36(N) means the inverter circuits 14 convert a plurality of write bitlines 32(0)-32(N) into the plurality of complementary write bitlines 36(0)-36(N). In this manner, eliminating the need to extend tracks along the width of the semiconductor die 44, instead allowing the tracks to be extend locally from the inverter circuits 14 to the two multi-port memory bitcells 16(0), 16(1). Since the plurality of complementary write bitlines 36(0)-36(N) is only routed to the adjacent multi-port memory bitcells 16(0), 16(1), the complementary write bitlines 36(0)-36(N) can be locally routed in any free area in the metal layers of the semiconductor die 44.

With continued reference to FIG. 3A, extra routing tracks requiring longer continuous areas to extend beyond the memory bitcell cluster 10-1 can be eliminated because of the locally generated complementary bitlines 36(0)-36(N) generated by the inverter circuits 14. The exemplary memory bitcell cluster 10-1 has a combined total of eighteen (18) read bitlines and write bitlines, as a non-limiting example. In this exemplary memory bitcell cluster 10-1, there are eighteen (18) total bitline ports and each bitline port typically requires eighteen (18) corresponding bitline tracks. In this example, the eighteen (18) corresponding bitline tracks are comprised of eight (8) read bitline tracks+five (5) write bitline tracks+five (5) write bitline complement tracks to properly route each bitline. However, in the exemplary embodiment, using the scheme in FIG. 3A, only five (5) write bitlines+eight (8) read bitlines, or thirteen (13) bitlines combined, are required to extend beyond the memory bitcell cluster 10-1 instead of eighteen (18) total bitlines. The reduction is because five (5) complementary write bitlines are generated locally using the write bitlines 32(0)-32(N) and the inverter circuits 14, and do not have to extend the length or width of the semiconductor die 44. Further, in this non-limiting example, a the number of inverters used may be reduced by half, as opposed to having a dedicated inverter circuit 14 for each complementary bitline 36(0)-36(N). This reduction is possible since the inverter circuits 14 are shared between two adjacent multi-port memory bitcells 16(0), 16(1). In an alternative embodiment, with more than two (2) memory bitcells 16(0), 16(1) sharing the inverters in the inverter circuits 14, the reduction of the number of inverters may be more than half, since more than two (2) memory bitcells 16(0), 16(1) would be sharing the same inverter circuits 14.

In this regard, FIG. 3B is an exemplary side view schematic and layout of the memory bitcell cluster 10-1 of FIG. 3A. A side view 49 of the memory bitcell cluster 10-1 illustrates the complementary write bitlines 36(0)-36(N) coupling the first and second memory bitcells 16(0), 16(1) to the inverter circuits 14. Also illustrated is a space gap 50 between the first memory bitcell 16(0) and the second memory bitcell 16(1) created because of wordline routing tracks. The exemplary side view 49 of the memory bitcell cluster 10-1 illustrates that while the write bitlines 32(0)-32(N) extend beyond the localized memory bitcell cluster region 42 of the memory bitcell cluster 10-1, the complementary write bitlines 36(0)-36(N) do not extend beyond the localized memory bitcell cluster region 42. In this regard, the memory bitcell cluster 10-1 employs localized generation of the complementary write bitlines 36(0)-36(N). By employing localized generation of the complementary write bitlines 36(0)-36(N) routing tracks for the complementary write bitlines 36(0)-36(N) are only necessary to extend within the localized memory bitcell cluster region 42.

In this regard, FIG. 4 is an exemplary schematic and layout of the memory bitcell cluster 10-1 of FIG. 3A illustrating wordline track usage of the memory bitcell cluster 10-1. The exemplary memory bitcell cluster 10-1 shows the plurality of first write wordlines 28(0)(0)-28(0)(N) and first read wordlines 48(0)(0)-48(0)(P) for the first multi-port memory bitcell 16(0) and the plurality of second write wordlines 28(1)(0)-28(1)(N), 48(1)(0)-48)(1)(P) for the second multi-port memory bitcell 16(1). The first memory bitcell 16(0) is not as wide as a first width 52 (W1) of the write and read wordlines 28(0)(0)-28(0)(N), 48(0)(0)-48(0)(P) for the first memory bitcell 16(0). Additionally a second width 54 (W2) of the second memory bitcell write and read wordlines 28(1)(0)-28(1)(N), 48(1)(0)-48(1)(P) is illustrated which shows the width of the wordlines for the second memory bitcell 16(1). The second memory bitcell write and read wordlines 28(1)(0)-28(1)(N), 48(1)(0)-48(1)(P) are wider than the second memory bitcell 16(1). The wordlines 28(0)(0)-28(0)(N), 28(1)(0)-28(1)(N), 48(0)(0)-48(0)(P), 48(1)(0)-48(1)(P), extend in a vertical direction (V) for the memory bitcell cluster 10-1. Based on the first width 52 and the second width 54, there is additional spacing between the first memory bitcell 16(0) and the second memory bitcell 16(1).

In this regard in FIG. 4, as a non-limiting example, the exemplary memory bitcell cluster 10-1 comprises two multi-port memory bitcells 16(0), 16(1). The first memory bitcell 16(0) comprises thirteen write and read wordline ports 28(0)(0)-28(0)(N) 48(0)(0)-48(0)(P) that may be placed in available metal layers (e.g. Metal 1, Metal 2, etc.) of the semiconductor die 44 or integrated circuit. The second memory bitcell 16(1) comprises thirteen (13) write and read wordline ports 28(1)(0)-28(1)(N) 48(1)(0)-48(1)(P) that may be placed in available metal layers (e.g., M1, M2, M5, etc.) of the semiconductor die 44 or integrated circuit. The multi-port memory bitcells 16(0), 16(1), are shown with the inverter circuits 14 localized between the two multi-port memory bitcells 16(0), 16(1). FIG. 4 also illustrates that the thirteen wordline ports will require more physical width than either the first multi-port memory bitcell 16(0) or the second multi-port memory bitcell 16(1). In this manner, the overall width required to place the multi-port memory bitcells 16(0), 16(1), in the semiconductor die 44 will be determined by the width of the wordlines 28(0)(0)-28(0)(N), 28(1)(0)-28(1)(N), 48(0)(0)-48(0)(P), 48(1)(0)-48(1)(P), not the devices or components comprised within the multi-port memory bitcells 16(0), 16(1). This construction is otherwise known as being metal limited. In this example, even though the multi-port memory bitcells 16(0), 16(1), are placed as physically close as possible because of the wordline track width, there still remains space to place the inverter circuits 14 between the two multi-port memory bitcells 16(0), 16(1). In this manner, the inverter circuits 14 may be shared between the two multi-port memory bitcells 16(0), 16(1) using a localized plurality of complementary write bitlines 36(0)-36(N).

In this regard, FIG. 5 is an exemplary schematic and layout of a Metal 2 layer of the memory bitcell cluster 10-1 of FIG. 3A illustrating horizontal bitline tracks 56 in a thirteen port memory bitcell cluster, as an example. As the density of the Metal 2 layer increases, it becomes increasingly difficult to use a traditional bitcell approach having dedicated bitline and complementary bitline tracks that extend the width of the semiconductor die 44. The localization of the inverter circuits 14 allows the plurality of complementary write bitlines 36(0)-36(N) to use localized for the complementary write bitline tracks 58. The localized complementary write bitline tracks 58 will extend from the inverter circuits 14 to the first multi-port memory bitcell 16(0) and to the second multi-port memory bitcell 16(1). In this manner, only the localized complementary write bitline tracks 58 used for the write bitlines 32(0)-32(N), as shown in FIG. 3A, are necessary to extend the width of the semiconductor die 44. The localized complementary write bitline tracks 58 extend horizontally across the semiconductor die 44, whereas the wordline tracks 28(0)(0)-28(0)(N), 28(1)(0)-28(1)(N), 48(0)(0)-48(0)(P), 48(1)(0)-48(1)(P) extend vertically.

The multi-port memory bitcells 16(0), 16(1) of FIG. 3A employing localized generation of complementary bitlines 36(0)-36(N) to reduce memory area, and related systems and methods according to embodiments disclosed herein, may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

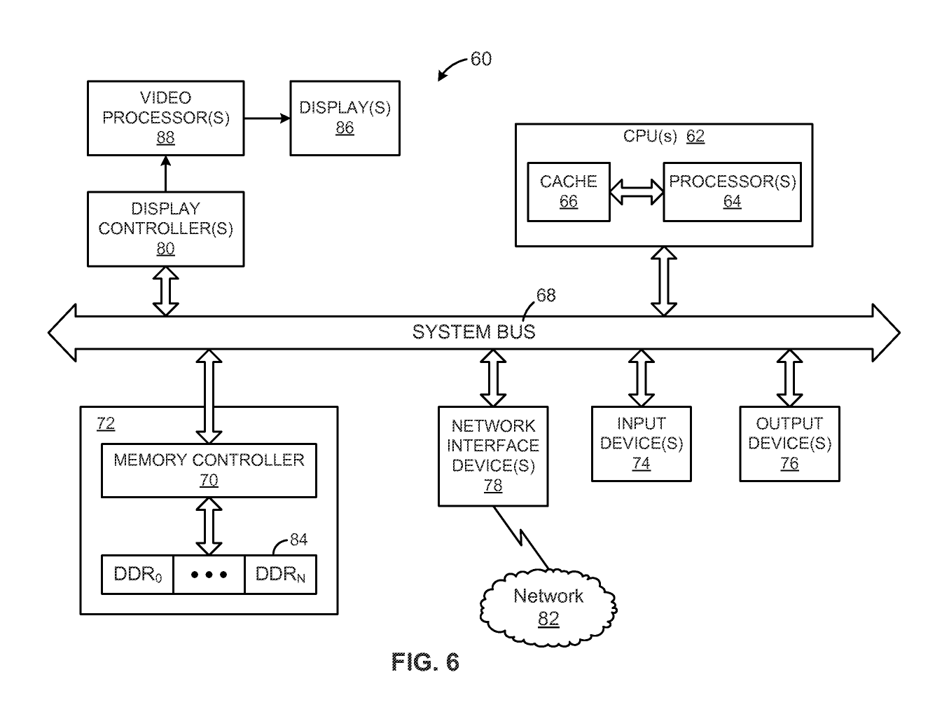

In this regard, FIG. 6 illustrates an example of a processor-based system 60 that can employ the memory bitcells 16(0), 16(1), employing localized generation of complementary bitlines to reduce memory area. In this example, the processor-based system 60 includes one or more central processing units (CPUs) 62, each including one or more processors 64. The CPU(s) 62 may have cache memory 66 coupled to the processor(s) 64 for rapid access to temporarily stored data. The CPU(s) 62 is coupled to a system bus 68 and can intercouple master and slave devices included in the processor-based system 60. As is well known, the CPU(s) 62 communicates with these other devices by exchanging address, control, and data information over the system bus 68. For example, the CPU(s) 62 can communicate bus transaction requests to a memory controller 70 as an example of a slave device. Although not illustrated in FIG. 6, multiple system buses 68 could be provided, wherein each system bus 68 constitutes a different fabric.

Other master and slave devices can be connected to the system bus 68. As illustrated in FIG. 6, these devices can include a memory system 72, one or more input devices 74, one or more output devices 76, one or more network interface devices 78, and one or more display controllers 80, as examples. The input device(s) 74 can include any type of input device, including but not limited to input keys, switches, voice processors, etc. The output device(s) 76 can include any type of output device, including but not limited to audio, video, other visual indicators, etc. The network interface device(s) 78 can be any devices configured to allow exchange of data to and from a network 82. The network 82 can be any type of network, including but not limited to a wired or wireless network, a private or public network, a local area network (LAN), a wide local area network (WLAN), and the Internet. The network interface device(s) 78 can be configured to support any type of communication protocol desired. The memory system 72 can include one or more memory units 84(0-N).

The CPU(s) 62 may also be configured to access the display controller(s) 80 over the system bus 68 to control information sent to one or more displays 86. The display controller(s) 80 sends information to the display(s) 86 to be displayed via one or more video processors 88, which process the information to be displayed into a format suitable for the display(s) 86. The display(s) 86 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a processor, a DSP, an Application Specific Integrated Circuit (ASIC), an FPGA or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A memory bitcell cluster, comprising:
a first memory bitcell comprising a first bit storage unit, a first wordline port configured to receive a first data access request from a first wordline to provide data access to the first bit storage unit, a first bitline port configured to carry data corresponding to the first bit storage unit on a bitline, and a first complementary bitline port configured to carry complementary data corresponding to the first bit storage unit on a complementary bitline;
a second memory bitcell adjacent to the first bitcell, the second bitcell comprising a second bit storage unit, a second wordline port configured to receive a second data access request from a second wordline to provide data access to the second bit storage unit, a second bitline port configured to carry data corresponding to the second bit storage unit on the bitline, and a second complementary bitline port configured to carry complementary data corresponding to the second bit storage unit on the complementary bitline; and
an inverter circuit configured to receive data on the bitline in an inverter input port, and invert the data to provide corresponding complementary data on an inverter output port to provide the complementary bitline.

2. The memory bitcell cluster of claim 1, wherein the inverter circuit is localized to the first memory bitcell and the second memory bitcell.

3. The memory bitcell cluster of claim 1, wherein the complementary bitline is localized to the first memory bitcell and the second memory bitcell.

4. The memory bitcell cluster of claim 1, wherein the first memory bitcell and the second memory bitcell are each configured to receive the complementary data from the inverter output port on the complementary bitline.

5. The memory bitcell cluster of claim 1, wherein the complementary bitline does not extend beyond a localized area defining the memory bitcell cluster.

6. The memory bitcell cluster of claim 1, wherein:
the first memory bitcell comprises:
a plurality of first wordline ports each configured to receive the first data access request from the first wordline to provide the first data access request to the first bit storage unit;
a plurality of first bitline ports each configured to carry the data corresponding to the first bit storage unit on the bitline; and
a plurality of first complementary bitline ports each configured to carry the complementary data corresponding to the first bit storage unit on the complementary bitline; and
the second memory bitcell comprises:
a plurality of second wordline ports each configured to receive the second data access request from the second wordline to provide the second data access request to the second bit storage unit;
a plurality of second bitline ports each configured to carry the data corresponding to the second bit storage unit on the bitline; and
a plurality of second complementary bitline ports each configured to carry the complementary data corresponding to the second bit storage unit on the complementary bitline; and
the inverter circuit comprises:
a plurality of inverters each configured to:
receive on an inverter input port, data from a bitline among the plurality of bitlines; and
invert the received data to provide the corresponding complementary data on a plurality of inverter output ports to provide the complementary bitline.

7. The memory bitcell cluster of claim 1, wherein:
the first wordline port is comprised of a single read wordline port and a single write wordline port; and
the second wordline port is comprised of a single read wordline port and a single write wordline port.

8. The memory bitcell cluster of claim 1, wherein:
the first bitline port is comprised of a first read bitline port and a first write bitline port; and
the second bitline port is comprised of a second read bitline port and a second write bitline port.

9. The memory bitcell cluster of claim 6, wherein:
the plurality of first wordline ports is comprised of a first plurality of read wordline ports and a first plurality of write wordline ports; and
the plurality of second wordline ports is comprised of a second plurality of read wordline ports and a second plurality of write wordline ports.

10. The memory bitcell cluster of claim 6, wherein:
the plurality of first bitline ports is comprised of a first plurality of read bitline ports and a first plurality of write bitline ports; and
the plurality of second bitline ports is comprised of a second plurality of read bitline ports and a second plurality of write bitline ports.

11. The memory bitcell cluster of claim 9, wherein:
the number of the first plurality of write wordline ports does not equal the number of the first plurality of read wordline ports; and
the number of the second plurality of write wordline ports does not equal the number of the second plurality of read wordline ports.

12. The memory bitcell cluster of claim 1, further comprising a third memory bitcell adjacent to the first memory bitcell and the second memory bitcell, the third memory bitcell comprising a third bit storage unit, a third wordline port configured to receive a third data access request from a third wordline to provide data access to the third bit storage unit, a third bitline port configured to carry data corresponding to the third bit storage unit on the bitline, and a third complementary bitline port configured to carry complementary data corresponding to the third bit storage unit on the complementary bitline.

13. The memory bitcell cluster of claim 1 comprised of a static random access memory (SRAM) bitcell cluster.

14. The memory bitcell bluster of claim 1 comprised of a register file bitcell cluster.

15. The memory bitcell cluster of claim 1 integrated into an integrated circuit die.

16. The memory bitcell cluster of claim 1, integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

17. A memory bitcell cluster for inverting a received first data access request and a received second data access request in the memory bitcell cluster, comprising:
a means for receiving a first data access request in a first memory bitcell means comprising a first bit storage means, a first wordline port means configured to receive the first data access request from a first wordline means to provide data access to the first bit storage means, a first bitline port means configured to carry data corresponding to the first bit storage means on a bitline means, and a first complementary bitline port means configured to carry complementary data corresponding to the first bit storage means on a complementary bitline means;
a means for receiving a second data access request in a second memory bitcell means adjacent to the first memory bitcell means, the second memory bitcell means comprising a second bit storage means, a second wordline port means configured to receive the second data access request from a second wordline means to provide data access to the second bit storage means, a second bitline port means configured to carry data corresponding to the second bit storage means on the bitline means, and a second complementary bitline port means configured to early complementary data corresponding to the second bit storage means on the complementary bitline means; and
a means for inverting, comprising an inverter circuit means configured to receive data on the bitline means in an inverter input port means, and invert the received data to provide corresponding complementary data on an inverter output port means to provide the complementary bitline means.

18. A method of localizing complementary bitlines in a memory bitcell cluster, comprising:
receiving a first data access request in a first memory bitcell comprising a first bit storage unit, comprising:
receiving, at a first wordline port, the first data access request from a first wordline to provide data access to the first bit storage unit;
carrying data on a first bitline port corresponding to the first bit storage unit on a bitline; and
carrying complementary data on a first complementary bitline port corresponding to the first bit storage unit on a first complementary bitline; and
receiving a second data access request in a second memory bitcell adjacent to the first bitcell, comprising:
receiving, at a second wordline port, the second data access request from a second wordline to provide data access to a second bit storage unit;
carrying data on a second bitline port corresponding to the second bit storage unit on the bitline; and
carrying complementary data on a second complementary bitline port corresponding to the second bit storage unit on a second complementary bitline; and
receiving data at an inverter input port of an inverter circuit; and
inverting the data received at inverter input port to provide corresponding complementary data on an inverter output port to provide the complementary bitline.

19. The method of claim 18, wherein inverting the received data comprises inverting the data locally to the first memory bitcell and the second memory bitcell.

20. The method of claim 18, wherein carrying the complementary data comprises carrying the complementary data locally to the first memory bitcell and the second memory bitcell.

21. The method of claim 18, wherein localizing of the complementary bitlines comprises not extending the complementary bitlines beyond a localized area defining the memory bitcell cluster.

22. The method of claim 18, wherein:
receiving the first data access request in the first memory bitcell comprises:
receiving the first data access request, further comprises receiving the first data access request at a plurality of first wordline ports, each first wordline port receiving the first data access request from the first wordline to provide the first data access request to the first bit storage unit;
carrying the data, further comprises carrying the data at a plurality of first bitline ports, each first bitline port carrying the data corresponding to the first bit storage unit on the bitline; and
carrying the complementary data, further comprises carrying the data at a plurality of first complementary bitline ports, each first complementary bitline port carrying the complementary data corresponding to the first bit storage unit on the complementary bitline;
receiving the second data access request in the second memory bitcell comprises:
receiving the second data access request, at a plurality of second wordline ports the second data access request, each second wordline port receiving the second data access request from the second wordline to provide the second data access request to the second bit storage unit;
carrying the data, at a plurality of second bitline ports, each second bitline port carrying the data corresponding to the second bit storage unit on the bitline; and
carrying the complementary data, at a plurality of second complementary bitline ports, each second complementary bitline port carrying the complementary data corresponding to the second bit storage unit on the complementary bitline; and
inverting the received data comprises:
receiving the data, further comprises receiving the data at a plurality of inverters, each inverter receiving the data on a plurality of bitlines coupled to a plurality of inverter input ports; and
inverting the received data, further comprises inverting the received data to provide the corresponding complementary data on a plurality of inverter output ports to provide the complementary bitline.

23. The method of claim 18, wherein:
receiving the first data access request at the first wordline port comprises receiving the first data access request at a first read wordline port or receiving the first data access request at a first write wordline port; and
receiving the second data access request at the second wordline port comprises receiving the second data access request at a second read wordline port or receiving the second data access request at a second write wordline port.

24. The method of claim 18, wherein:
carrying the data on the first bitline port comprises carrying the data on a first read bitline port and a first write bitline port; and
carrying the data on the second bitline port comprises carrying the data on a second read bitline port and a second write bitline port.

25. The method of claim 22, wherein:
receiving the first data access request at the plurality of first wordline ports, further comprises receiving the first data access request at a plurality of first read wordline ports or receiving the first data access request at a plurality of first write wordline ports; and
receiving the second data access request at the plurality of second wordline ports, further comprises receiving the second data access request at a plurality of second read wordline ports or receiving the second data access request at a plurality of second write wordline ports.

26. The method of claim 22, wherein:
carrying the data on a plurality of first bitline ports, further comprises carrying the data on a plurality of first read bitline ports or carrying the data on a plurality of first write bitline ports; and
carrying the data on a plurality of second bitline ports, further comprises carrying the data on a plurality of second read bitline ports or carrying the data on a plurality of second write bitline ports.

27. The method of claim 25, wherein:
receiving data access requests on a number of the plurality of first write wordline ports, further comprises receiving data access requests on a number of the plurality of first write wordline ports different from a number of data access requests at a plurality of first read wordline ports; and
receiving data access requests on a number of the plurality of second write wordline ports, further comprises receiving the data access requests on a number of the plurality of second write wordline ports different from a number of the data access requests at the plurality of second read wordline ports.
